(19) United States
(12) Patent Application Publication
(10) Pub. No.: US 2013/0170123 A1
(43) Pub. Date: Jul. 4, 2013

(54) REINFORCING STRUCTURE FOR SLIM KEYBOARDS

(71) Applicant: Chin-Hsiu HWA, New Taipei City (TW)

(72) Inventor: Chin-Hsiu HWA, New Taipei City (TW)

(21) Appl. No.: 13/342,544

(22) Filed: Jan. 3, 2012

(51) Int. Cl. H05K 7/00

(52) U.S. Cl. 361/679.08

(57) ABSTRACT

A reinforcing structure for a slim keyboard includes a baseboard with a plurality of coupling portions, a top board including at least one opening and connecting to the baseboard, and at least one keyboard portion coupling with one coupling portion and movable within the opening of the top board and against the a circuit board to form a depressing movement and generate a key command signal. The baseboard has a reinforcing portion extended vertically upwards from one end thereof via a first bending line, and the reinforcing portion has a connecting portion extended horizontally outwards from one end thereof via a second bending line. The connecting portion and top board have respectively at least one fastening hole and fastening portion that are run through by a fastening element for fastening. The reinforcing structure thus formed improves stroke feedback feeling, makes the keyboard lighter, and reduces assembly process and cost.

### FIELD OF THE INVENTION

The present invention relates to a keyboard structure and particularly to a reinforcing structure for slim keyboards.

### BACKGROUND OF THE INVENTION

Keyboard is a device mainly for entering commands into a computer system. Nowadays use environments and timing of the computer system are more diversified, developments of the keyboard also have to meet those diversified requirements. For instance, to enable unskillful users to stroke the keys accurately in a low luminosity or dim environment, various types of illuminated keyboards have been developed, such as U.S. Pat. Nos. 5,936,554 and 7,278,750, and R.O.C. patent Nos. 566612 and 581961. They all provide an illuminated keyboard with multiple keys each corresponding to at least one light-emitting diode (LED). Such type of illuminated keyboard requires a great number of LEDs. Total element number increases, more fabrication processes are needed and the cost is higher. The finished product also cannot be made lighter. Moreover, the LEDs generate a lot of waste heat and consume a great amount of electric power. All this creates a lot of problems to users.

To remedy the aforesaid disadvantages, another type of illuminated keyboard has been developed, such as U.S. Pat. Nos. 6,179,432, 6,199,996, 6,217,183, 6,284,988, 6,322,229, 6,554,442, 6,590,508, 6,648,530, 6,860,612, 7,235,752, 7,239,303 and 7,388,167, and R.O.C. patent Nos. 509955, 516671, 587800, 594546, I230957, I231693, M240668 and M313281. They mainly provide a lighting back plate such as an electroluminescent sheet or an optical fiber panel to replace the LEDs. As such a keyboard can provide uniform illumination through a single lighting back plate, it has fewer internal elements and makes assembly easier. Moreover, since the lighting back plate consumes less electric power, it is operable for a longer duration.

However, no matter using the LEDs or lighting back plate as the main lighting element of the illuminated keyboard, it still needs to install an extra lighting element comparing with the conventional non-illuminated keyboard, and results in greater thickness and weight. Moreover, in order to improve stroke feedback feeling, U.S. Pat. No. 6,987,466 and R.O.C. publication No. 200529048 disclose an illuminated keyboard with a hard bottom board to hold the lighting back plate and baseboard to provide a firmer support for the keyboard portion mounted onto the baseboard. On the other hand, to make the keyboard lighter and have illumination capability, other types of illuminated keyboards without having the bottom board also have been developed that merely use a baseboard and lighting back plate to hold depressing elements, such as U.S. publication Nos. 2010026528 and 2010103644, and R.O.C. patent No. M408732. As these keyboard portions can not be supported by a hard bottom board and the baseboard and lighting back plate do not have sufficient structural strength, the baseboard holding the depressing elements easily deforms under external forces, thus the stroke feedback feeling of the users suffers.

Furthermore, the conventional illuminated keyboard generally includes a baseboard to carry depressing elements, a top board to hold the depressing elements and a lighting back plate located between the baseboard and top board. To assemble the baseboard, lighting back plate and top board together to become the illuminated keyboard, the baseboard and lighting back plate respectively have multiple mating fastening holes while the top board has fastening portions corresponding to the fastening holes, and a great number of fastening elements is used to fasten the fastening holes and fastening portions together. All this creates more unnecessary weight on the keyboard and makes reducing the weight more difficult. More assembly processes are required and the cost also increases.

### SUMMARY OF THE INVENTION

The primary object of the present invention is to increase the structural strength of a baseboard without easily bending or warping under external forces.

Another object of the invention is to finish assembly of a keyboard with fewer fastening elements to reduce total weight so that the keyboard can be made lighter and with reduced assembly processes and cost.

To achieve the foregoing objects, the present invention provides a reinforcing structure for slim keyboards that includes a baseboard with a plurality of coupling portions, a top board including at least one opening and connecting to the baseboard, and at least one keyboard portion coupling with one coupling portion and movable up and down within the opening of the top board and against a circuit board to form a depressing movement and generate a key command signal. The reinforcing structure is characterized in that the baseboard has a reinforcing portion extended vertically upwards from one end thereof via a first bending line, and the reinforcing portion has a connecting portion extended horizontally outwards from one end thereof via a second bending line. The connecting portion and top board have respectively at least one fastening hole and at least one fastening portion that are corresponding to each other and run through by a fastening element for fastening together.

In one embodiment the keyboard portion includes a keycap located in the opening, a bridge driven member bridging the keycap and coupling portion, and an elastic element located in the bridge driven member.

In one embodiment the circuit board is located between the baseboard and top board.

In one embodiment the circuit board is located below the baseboard.

In one embodiment a lighting assembly is located between the baseboard and top board.

In one embodiment the baseboard includes at least one reinforcing rib on vacant area where no coupling portion is formed.

In one embodiment a lighting assembly is located below the baseboard.

In one embodiment a support seat is added below the baseboard that has a support portion corresponding to the connecting portion.

By means of the foregoing structure, the reinforcing portion is extended vertically upwards from one end of the baseboard via the first bending line, and the connecting portion is extended horizontally outwards from one end of the reinforcing portion via the second bending line so that the reinforcing portion and connecting portion are connected to form a stepped structure without being easily bent or warped. Hence the structural strength of the baseboard increases and the stroke feedback feeling also enhances. Moreover, the connecting portion and top board have respectively at least one fastening hole and at least one fastening portion that are corresponding to each other and run through by a fastening element for fastening. Assembly of the keyboard can be accomplished with fewer fastening elements. Therefore the keyboard can be made lighter, and the assembly processes and cost can be reduced.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a top exploded view of an embodiment of the invention.

FIG. 2 is bottom exploded view of an embodiment of the invention.

FIG. 3 is a fragmentary enlarged view of an embodiment of the baseboard of the invention.

FIG. 4 is top exploded view of another embodiment of the invention.

FIG. 5 is a schematic view of an embodiment of the invention showing the baseboard with at least one reinforcing rib.

FIG. 6 is a schematic view of another embodiment of the invention showing the baseboard with at least one reinforcing rib.

FIGS. 7 through 10 are sectional views of various embodiments of the invention showing the reinforcing structure adopted on an illuminated keyboard.

### DETAILED DESCRIPTION OF THE PREFERRED EMBODIMENTS

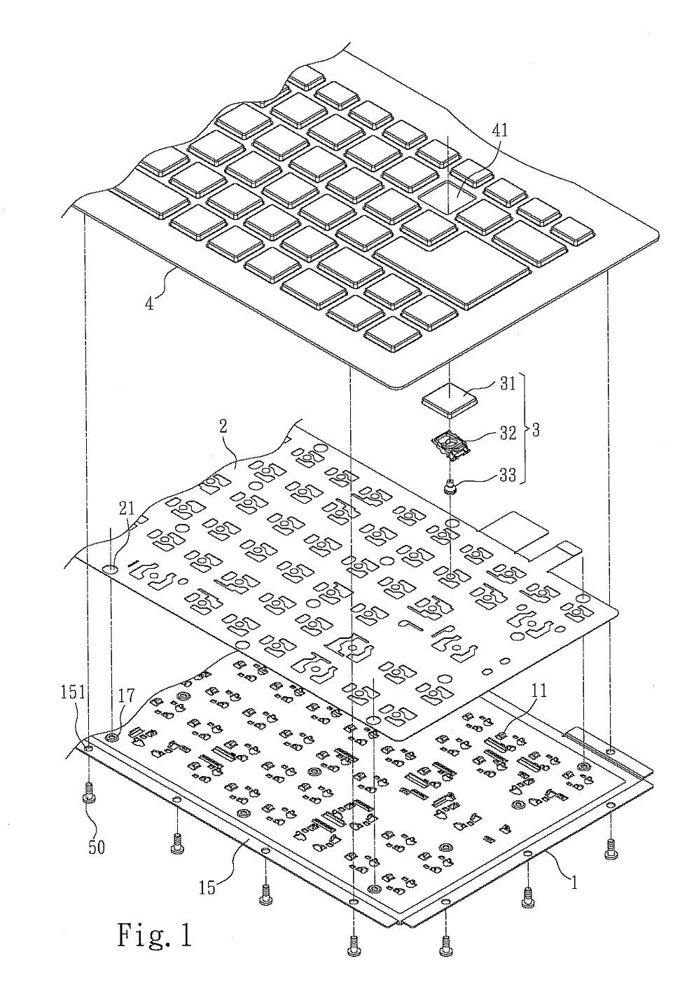

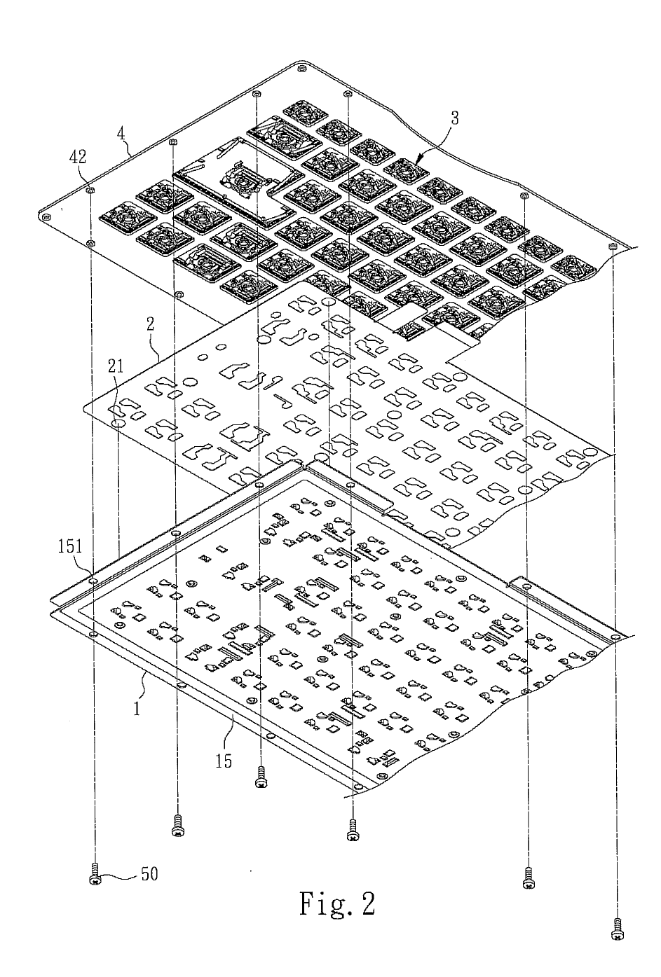

Please refer to FIGS. 1 and 2 for an embodiment of the invention. The reinforcing structure for slim keyboards according to the invention comprises a baseboard 1, a circuit board 2, at least one keyboard portion 3 and a top board 4. The baseboard 1 includes a plurality of coupling portions 11 to connect to the keyboard portion 3. The baseboard 1 and circuit board 2 have respectively a latch portion 17 and a corresponding aperture 21 run through by the latch portion 17 to position the circuit board 2 on the baseboard 1. The top board 4 is connected to the baseboard 1 and has at least one opening 41. The keyboard portion 3 is held in the opening 41 of the top board 4 and movable up and down against the circuit board 2 to form a depressing movement and generate a key command signal.

More specifically, the keyboard portion 3 includes a keycap 31, a bridge driven member 32 and an elastic element 33. FIG. 1 shows only one set for discussion. The bridge driven member 32 has an upper end and a lower end respectively connecting to the keycap 31 held in the opening 41 and the coupling portion 11 of the baseboard 1. The elastic element 33 is held in the bridge driven member 32. When in keystroke, the circuit board 2 is depressed by the elastic element 33 during up and down movement of the keycap 31 to generate and output a key command signal.

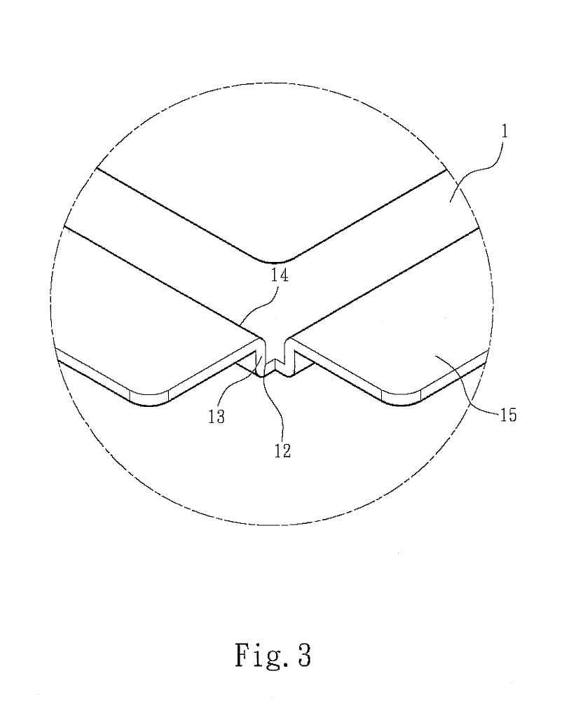

Also referring to FIG. 3, the baseboard 1 has a reinforcing portion 13 extended vertically upwards from one end thereof via a first bending line 12. The reinforcing portion 13 has a connecting portion 15 extended horizontally outwards from one end thereof via a second bending line 14. The reinforcing portion 13 and connecting portion 15 form a stepped structure at each of four ends of the baseboard 1. The stepped structure has a bending section respectively at the first bending line 12 and second bending line 14. The bending section is less likely bent or warped under external forces. Thus the baseboard 1 has a greater structural strength and not easily deforms under the external forces. Users also can get improved stroke feedback feeling.

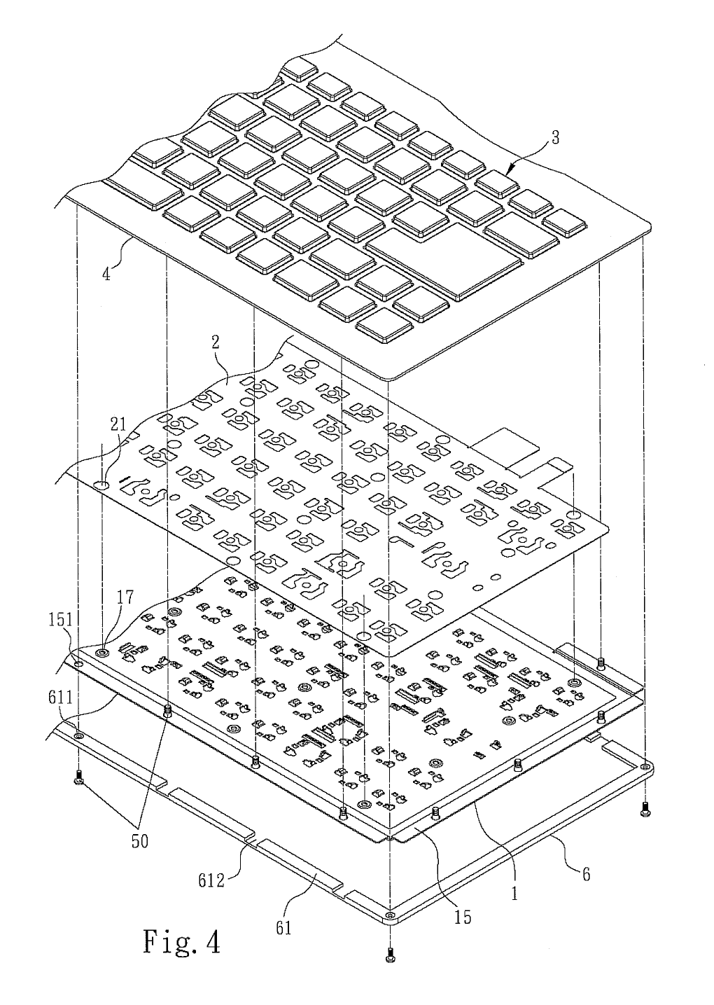

Also referring to FIGS. 1, 2 and 3, to facilitate fastening of the baseboard 1 and top board 4, the connecting portion 15 of the baseboard 1 has at least one fastening hole 151, and the top board 4 has at least one fastening portion 42 corresponding to the fastening hole 151. The baseboard 1 and top board 4 can be fastened together via a fastening element 50 running through the fastening hole 151 and fastening portion 42. The fastening element 50 can be a rivet or screw, but this is not the limitation. Thus, with mating fastening structures formed on the borders of the baseboard 1 and top board 4, only a small number of fastening elements is needed to finish assembly of the product. As a result, production and assembly processes of the keyboard can be reduced, and the cost also is lower. Please refer to FIG. 4 for another embodiment of the invention. In order to add a lighting assembly below the baseboard 1 and protect the baseboard 1 from being damaged by the external forces and further enhance the structural strength of the baseboard 1, a support seat 6 is provided below the baseboard 1 for holding the baseboard 1. The support seat 6 has a support portion 61 corresponding to the connecting portion 15. The support portion 61 has at least one positioning hole 611 corresponding to the fastening hole 151. The fastening element 50 runs through the positioning hole 611 and fastening hole 151 and fastens to the fastening portion 42.

The connecting portion 15 is spaced from the baseboard 1 at a height difference, and the support portion 61 is formed at a height just fit in that height difference. Moreover, the support portion 61 has a plurality of notches 61. The fastening elements 50 running through the fastening holes 151 and fastening to the fastening portions 42 can be held in the notches 612 to avoid separation of the support portion 61 and connecting portion 15, therefore the support portion 61 is tightly in contact with the connecting portion 15, and the bottom of the connecting portion 15 can be supported without being bending or warping under the external forces. As a result, the support portion 6, baseboard 1, circuit board 2, keyboard portion 3 and top board 4 are assembled to form a sturdier reinforcing structure of a slim keyboard.

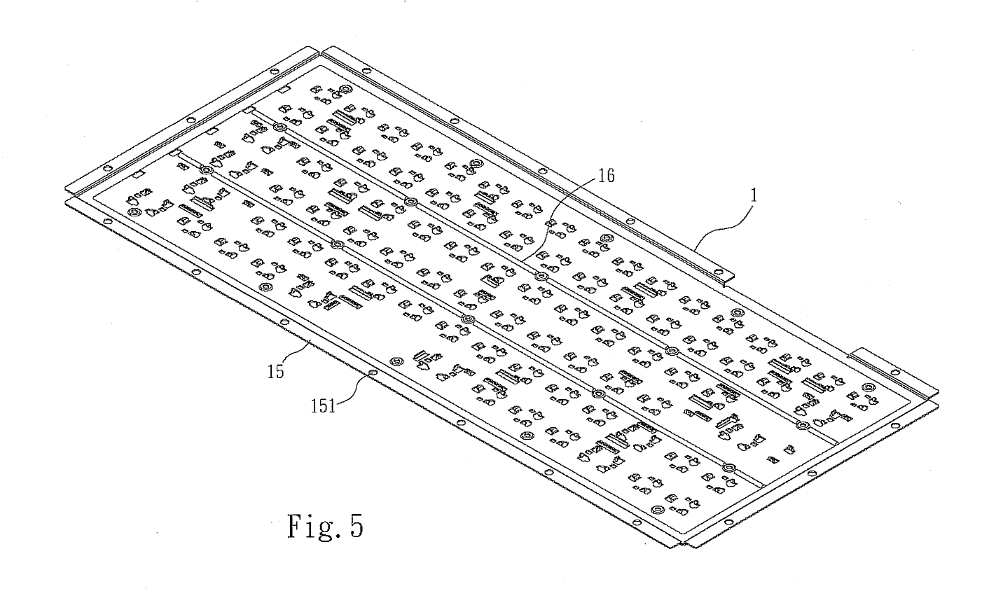

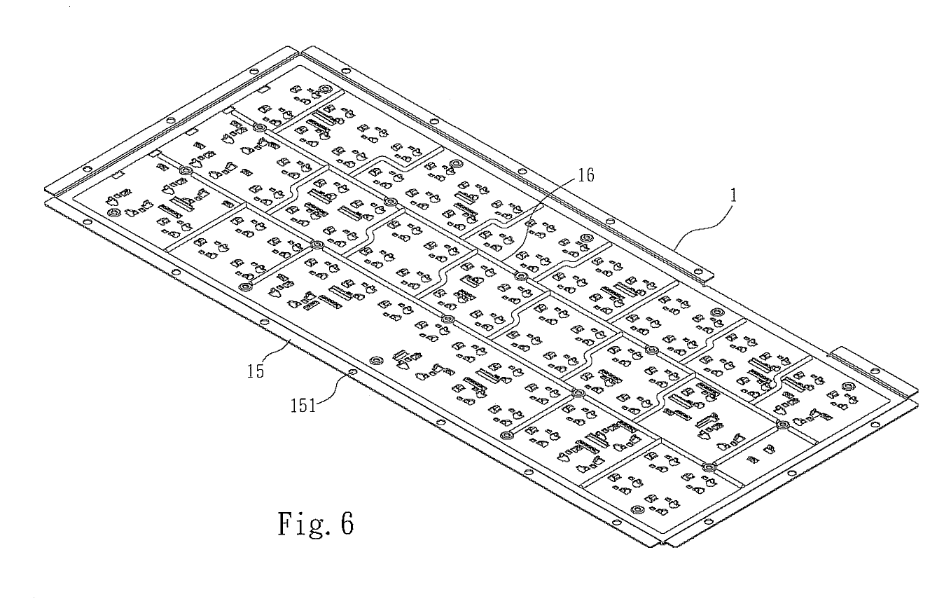

In addition, to further increase the structural strength of the baseboard 1, aside from the aforesaid embodiment by providing the support seat 6 located below the baseboard 1, referring to FIGS. 5 and 6, the baseboard 1 may have at least one reinforcing rib 16 on vacant area where no coupling portion 11 is formed. In FIG. 5 the reinforcing ribs 16 are arranged in the same direction without crossing each other on the vacant area to enhance the structural strength of the baseboard 1 in the direction parallel with the extending direction of the reinforcing ribs 16. In another embodiment shown in FIG. 6, the reinforcing ribs 16 are arranged in different directions and cross each other on the vacant area, hence the structural strength of the baseboard 1 is enhanced in all directions. The reinforcing rib 16 is preferably formed integrally with the baseboard 1 by stamping, but this is not the limitation of the invention.

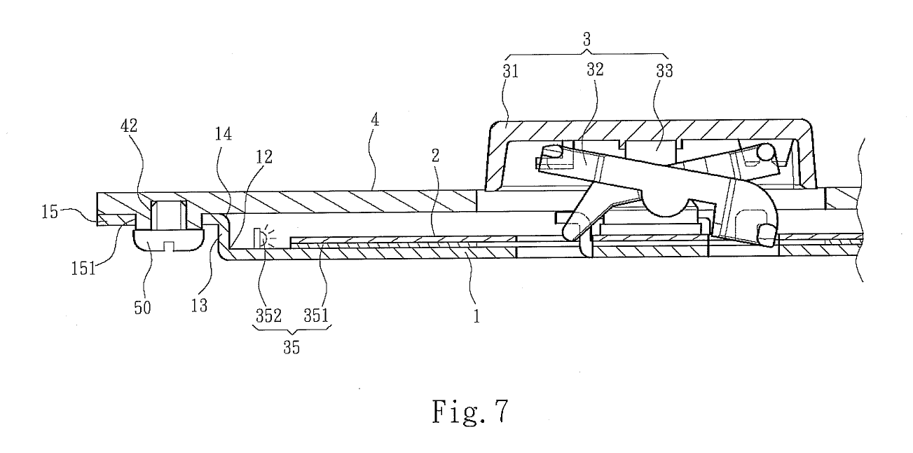

Apart from being adopted on the slim keyboard, the reinforcing structure of the invention also can be employed on a slim illuminated keyboard, referring to FIGS. 7 through 10 in various embodiments for such purpose. FIG. 7 illustrates one of the embodiments that mainly includes a baseboard 1, a circuit board 2, at least one keyboard portion 3 and a top board 4. The baseboard 1 has a reinforcing portion 13 extended vertically upwards from one end thereof via a first bending line 12. The reinforcing portion 13 has a connecting portion 15 extended horizontally outwards from one end thereof via a second bending line 14. The connecting portion 15 has a fastening hole 151 run through by a fastening element 50 to fasten to a fastening portion 42 formed on the top board 4, thus the baseboard 1 and the top board 4 are fastened together. The keyboard portion 3 includes a keycap 31, a bridge driven member 32, an elastic element 33 and a lighting assembly 35. The lighting assembly 35 includes a light guide plate 351 and a light source 352 to emit light. The light source 352 is located at one side of the light guide plate 351 and guides light via the light guide plate 351 to the keycap 31 for illumination. The positioning of the light source 352 shown in FIG. 7 merely serves for illustrative purpose and is not the limitation of the invention. In one embodiment, the bridge driven member 32 has one end connecting to the keycap 31 and another end anchored on the baseboard 1. The elastic element 33 is held in the bridge driven member 32 to connect to the circuit board 2. Movement of the keyboard portion 3 is the same as previously discussed, thus is omitted herein.

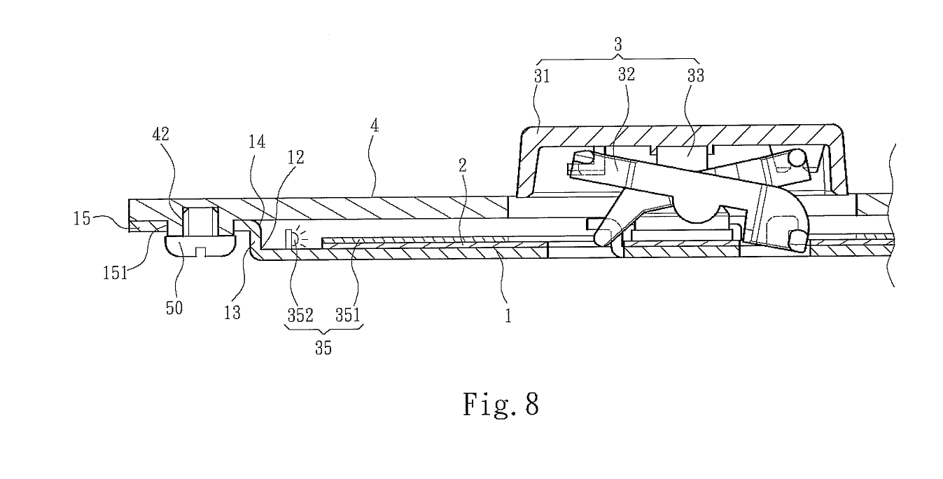

It is to be noted that the circuit board 2 and lighting assembly 35 are located between the baseboard 1 and top board 4 while the circuit board 2 is also located above the light guide plate 351 as shown in FIG. 7. FIG. 8 illustrates another embodiment which differs from the FIG. 7 by having the light guide plate 351 located above the circuit board 2. Furthermore, the lighting assembly 35 can be an electroluminescent sheet or optical fiber panel, and the electric power needed by the electroluminescent sheet or optical fiber panel to emit light can be obtained via the circuit board 2.

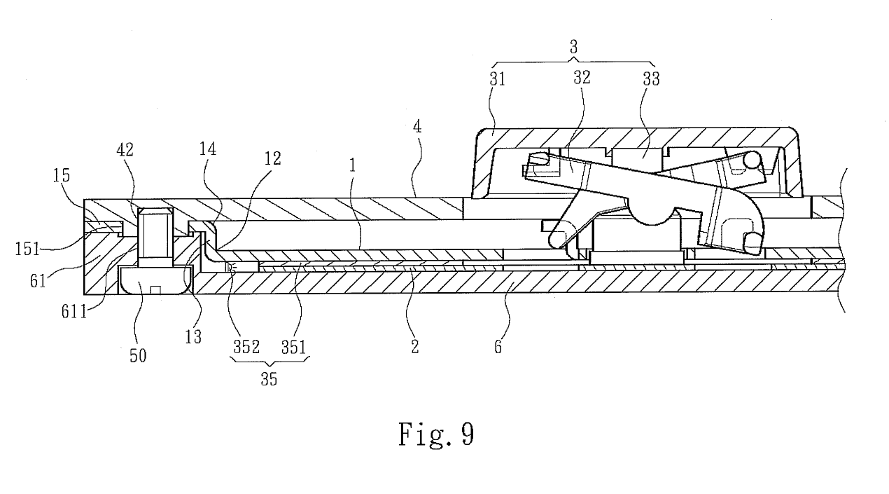

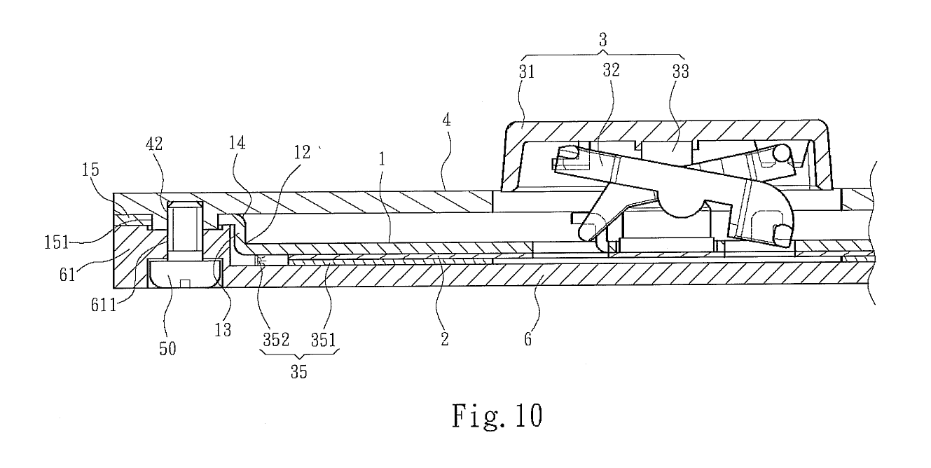

The circuit board 2 and lighting assembly 35 may also be located below the baseboard 1. In such an embodiment, a support seat 6 is provided below the circuit board 2 and lighting assembly 35 to support thereof. FIG. 9 shows yet another embodiment in which the light guide plate 351 is located above the circuit board 2. FIG. 10 shows still another embodiment with the circuit board 2 above the light guide plate 351. In the embodiments shown in FIGS. 9 and 10, a fastening element 50 is provided to run through the positioning hole 611 of the support portion 61 and the fastening hole 151 of the connecting portion 15 to fasten the baseboard 1 and support seat 6 to the top board 4.

As a conclusion, the reinforcing structure for slim keyboards according to the invention mainly provides a reinforcing portion extended vertically upward from one end of the baseboard via a first bending line, and a connecting portion extended horizontally outwards from one end of the reinforcing portion via a second bending line so that the reinforcing portion and the connecting portion are connected to form a stepped structure without being easily bending or warping. Therefore the structural strength of the baseboard is greatly enhanced without deforming under external forces. Moreover, the stroke feedback feeling also increases. In addition, as the baseboard is fastened to the top board via the connecting portions at the borders of the baseboard, only a small number of the fastening elements is needed for assembly, thus not only the weight of the keyboard can be reduced, but assembly process and cost also can be decreased. All this indicates that the invention provides significant improvements over the conventional techniques.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A reinforcing structure for slim keyboards, comprising a baseboard with a plurality of coupling portions, a top board including at least one opening and connecting to the baseboard, and at least one keyboard portion coupling with each of the plurality of coupling portions and movable up and down within the opening of the top board and against a circuit board to form a depressing movement and generate a key command signal, characterized in that:
the baseboard includes a reinforcing portion extended vertically upwards from one end thereof via a first bending line, the reinforcing portion including a connecting portion extended horizontally outwards from one end thereof via a second bending line, the connecting portion and the top board including respectively at least one fastening hole and at least one fastening portion that are corresponding to each other and run through by a fastening element for fastening.

2. The reinforcing structure for slim keyboards of claim 1, wherein the keyboard portion includes a keycap located in the opening, a bridge driven member connecting to the keycap and the coupling portion, and an elastic element located in the bridge driven member.

3. The reinforcing structure for slim keyboards of claim 1, wherein the circuit board is located between the baseboard and the top board.

4. The reinforcing structure for slim keyboards of claim 1, wherein the circuit board is located below the baseboard.

5. The reinforcing structure for slim keyboards of claim 1 further including a lighting assembly located between the baseboard and the top board.

6. The reinforcing structure for slim keyboards of claim 2 further including a lighting assembly located between the baseboard and the top board.

7. The reinforcing structure for slim keyboards of claim 3 further including a lighting assembly located between the baseboard and the top board.

8. The reinforcing structure for slim keyboards of claim 4 further including a lighting assembly located between the baseboard and the top board.

9. The reinforcing structure for slim keyboards of claim 5, wherein the baseboard includes at least one reinforcing rib on vacant area where no coupling portion is formed.

10. The reinforcing structure for slim keyboards of claim 6, wherein the baseboard includes at least one reinforcing rib on vacant area where no coupling portion is formed.

11. The reinforcing structure for slim keyboards of claim 7, wherein the baseboard includes at least one reinforcing rib on vacant area where no coupling portion is formed.

12. The reinforcing structure for slim keyboards of claim 8, wherein the baseboard includes at least one reinforcing rib on vacant area where no coupling portion is formed.

13. The reinforcing structure for slim keyboards of claim 1 further including a lighting assembly located below the baseboard.

14. The reinforcing structure for slim keyboards of claim 2 further including a lighting assembly located below the baseboard.

15. The reinforcing structure for slim keyboards of claim 13, wherein the baseboard includes at least one reinforcing rib on vacant area where no coupling portion is formed.

16. The reinforcing structure for slim keyboards of claim 14, wherein the baseboard includes at least one reinforcing rib on vacant area where no coupling portion is formed.

17. The reinforcing structure for slim keyboards of claim 1, wherein the baseboard includes at least one reinforcing rib on vacant area where no coupling portion is formed.

18. The reinforcing structure for slim keyboards of claim 2, wherein the baseboard includes at least one reinforcing rib on vacant area where no coupling portion is formed.

19. The reinforcing structure for slim keyboards of claim 1 further including a support seat located below the baseboard.

20. The reinforcing structure for slim keyboards of claim 19, wherein the support seat includes a support portion corresponding to the connecting portion of the baseboard.
